(19) United States
(12) Patent Application Publication
(10) Pub. No.: US 2010/0041220 A1
(43) Pub. Date: Feb. 18, 2010

(54) METHODS FOR UNIFORMLY OPTICALLY ANNEALING REGIONS OF A SEMICONDUCTOR SUBSTRATE

(75) Inventor: Harry J. LEVINSON, Saratoga, CA (US)

Correspondence Address: Ingrassia Fisher & Lorenz, P.C. (GF), 7010 E. Cochise Rd., Scottsdale, AZ, 85253, US

(73) Assignee: ADVANCED MICRO DEVICES, INC., Austin, TX (US)

(21) Appl. No.: 12/190,332

(22) Filed: Aug. 12, 2008

(51) Int. Cl. H01L 21/22; H01L 21/00

(52) U.S. Cl. 438/542; 438/795; 257/E21.134

(57) ABSTRACT

Methods for uniformly optically annealing regions of a semiconductor substrate and methods for fabricating semiconductor substrates using uniform optical annealing are provided. In accordance with an exemplary embodiment, a method for uniformly optically annealing a semiconductor substrate comprises the step of obtaining an optical reflectance of a first region of the semiconductor substrate. A second region of the semiconductor substrate is fabricated such that the optical reflectance of the second region is substantially equal to the optical reflectance of the first region, wherein the first region is not the second region. The semiconductor substrate is optically annealed.

### FIELD OF THE INVENTION

The present invention generally relates to methods for fabricating semiconductor structures, and more particularly relates to methods for uniformly optically annealing regions of a semiconductor substrate.

### BACKGROUND OF THE INVENTION

Optical annealing methods are commonly used during the fabrication of semiconductor devices. Such methods include rapid thermal annealing (RTA), rapid thermal cleaning (RTC), rapid thermal chemical vapor deposition (RTCVD), rapid thermal oxidation (RTO), and rapid thermal nitridation (RTN). These methods typically are performed using systems that heat a wafer using radiative energy generated by one or more lamps placed near the wafer. Optical absorption of the radiative energy by the wafer causes the temperature of the wafer to rise. The increase of the wafer temperature facilitates doping of the wafer, oxidation, and/or nitridation of the wafer, deposition of materials on the wafer, and the like.

A challenge with optical annealing methods involves the non-uniformity of temperature changes across the wafer during annealing. The optical absorption of the wafer is determined by the reflective properties of the wafer, that is, the light that is not reflected is absorbed. In turn, the reflective properties of the wafer are determined by the various material layers that have been deposited on the wafer and the various structures that have been formed on and/or within the wafer. Because different regions of a wafer may be composed of different structures of different materials, the optical absorption of the different regions also will be different. FIG. 1 is a graph 10 illustrating the reflection of red light (wavelength of 632.8 nanometers (nm)) from films of silicon nitride on a thin (10 nm thickness) oxide film on a silicon substrate. The x-axis 12 of the graph 10 designates the silicon nitride thickness in nanometers (nm) and the y-axis 14 of the graph 10 designates the light reflectance (fraction of light reflected). As can be seen from curve 16 of the graph, the reflectance can be modulated by the thickness of the silicon nitride film.

Thus, as the constitution of various regions of the wafer change, so does the light absorption of the various regions during annealing. The non-uniformity of light absorption across the various regions of the wafer results in temperature non-uniformity across these various regions. Such temperature non-uniformity can cause deviations from the desired characteristics of transistors and other devices formed on and within the wafer, leading to slow, less powerful, less efficient, and/or non-functioning devices.

Accordingly, it is desirable to provide methods for uniformly optically annealing regions of a semiconductor substrate. In addition, it is desirable to provide methods for fabricating semiconductor structures using uniform optical annealing of regions of a semiconductor substrate. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

A method for uniformly optically annealing a semiconductor substrate is provided in accordance with an exemplary embodiment of the present invention. The method comprises the step of obtaining an optical reflectance of a first region of the semiconductor substrate. A second region of the semiconductor substrate is fabricated such that the optical reflectance of the second region is substantially equal to the optical reflectance of the first region, wherein the first region is not the second region. The semiconductor substrate is optically annealed.

A method for fabricating semiconductor structures on a semiconductor substrate is provided in accordance with an exemplary embodiment of the present invention. The method comprises the step of obtaining an optical reflectance of a contemplated first region of the semiconductor substrate. The optical reflectance of the contemplated first region is compared to an optical reflectance of a contemplated second region of the semiconductor substrate. A constitution of the contemplated first region is modified to a constitution of a modified first region if the optical reflectance of the contemplated first region and the optical reflectance of the contemplated second region are not substantially similar. The modified first region of the semiconductor substrate is fabricated and the semiconductor substrate is optically annealed.

### BRIEF DESCRIPTION OF THE DRAWINGS

The present invention will hereinafter be described in conjunction with the following drawing figures, wherein like numerals denote like elements, and wherein:

FIG. 1 is a graph illustrating the reflection of light from films of silicon nitride on a 10 nm thick oxide film on a silicon substrate;

FIG. 2 is a flow chart of a method for fabricating semiconductor structures using a uniform optical annealing process in accordance with an exemplary embodiment of the present invention;

FIG. 3 is a cross-sectional view of a semiconductor substrate having two regions that exhibit different optical reflectance;

FIG. 4 is a cross-sectional view of a semiconductor substrate having a first region and a modified second region, with both regions exhibiting substantially the same optical reflectance, in accordance with an exemplary embodiment;

FIG. 5 is a cross-sectional view of a semiconductor substrate having a first region and a modified second region, with both regions exhibiting substantially the same optical reflectance, in accordance with another exemplary embodiment;

FIG. 6 is a cross-sectional view of a semiconductor substrate having a modified first region and a second region, with both regions exhibiting substantially the same optical reflectance, in accordance with a further exemplary embodiment;

FIG. 7 is a cross-sectional view of a semiconductor substrate having two regions that exhibit different optical reflectance;

FIG. 8 is a cross-sectional view of a semiconductor substrate having a first region and a modified second region, with both regions exhibiting substantially the same optical reflectance, in accordance with an exemplary embodiment;

FIG. 9 is a cross-sectional view of a semiconductor substrate having a first region and a modified second region, with both regions exhibiting substantially the same optical reflectance, in accordance with another exemplary embodiment;

FIG. 10 is a cross-sectional view of a semiconductor substrate having a modified first region and a second region, with both regions exhibiting substantially the same optical reflectance, in accordance with a further exemplary embodiment; and

FIG. 11 is a cross-sectional view the reflectance and transmittance of light incident on a single material layer.

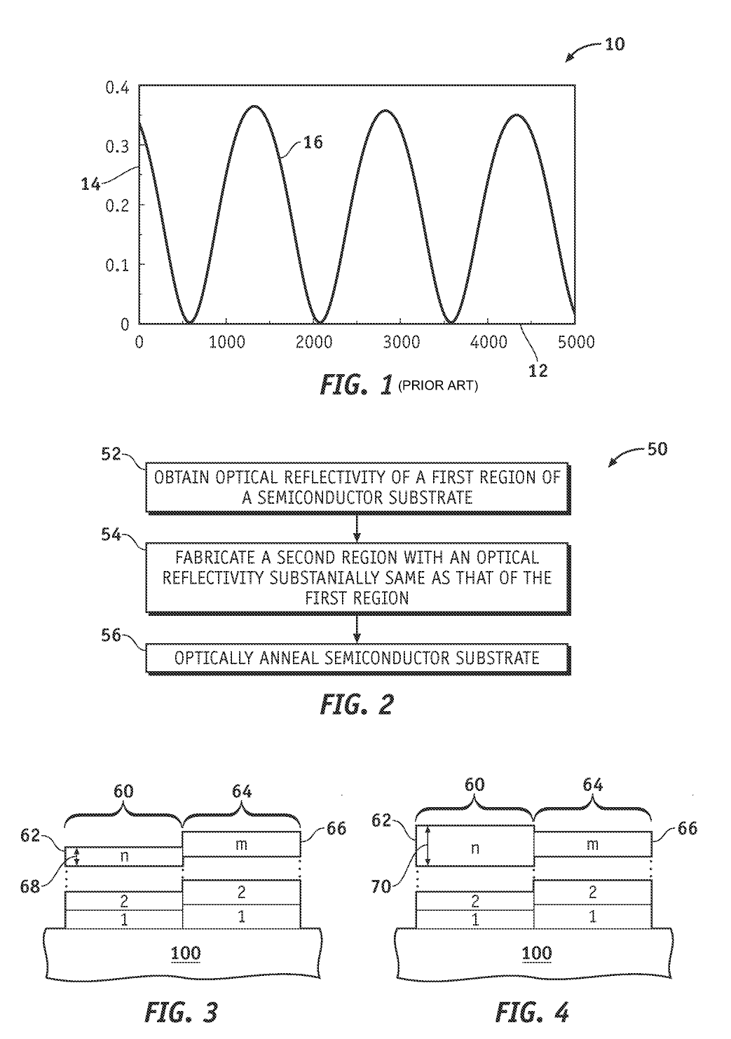

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

Methods for uniformly optically annealing a semiconductor substrate and methods for fabricating semiconductor structures using a uniform optical annealing process are provided herein. The methods utilize a comparison of the optical reflectance of a first region of a semiconductor substrate to the optical reflectance of a second region of the semiconductor substrate. At least one of the regions then is modified so that it exhibits the same optical reflectance as the other region. In this regard, during the simultaneous optical annealing of both regions of the semiconductor substrate, both regions exhibit substantially the same optical reflectance and, hence, absorption of light. This uniform optical reflectance, in turn, results in a substantially uniform temperature change of both regions, which uniformity minimizes deviations from the desired characteristics of devices or structures formed on and within the regions.

FIG. 2 is a flowchart of a method 50 for uniformly optically annealing different regions of a semiconductor substrate. The method 50 includes the step of obtaining the optical reflectance of a first region of a semiconductor substrate (step 52). As used herein, the term “semiconductor substrate” will be used to encompass semiconductor materials conventionally used in the semiconductor industry from which to make electrical devices. Semiconductor materials include monocrystalline silicon materials, such as the relatively pure or impurity-doped monocrystalline silicon materials typically used in the semiconductor industry, as well as polycrystalline silicon materials, and silicon admixed with other elements such as germanium, carbon, and the like. In addition, “semiconductor substrate” encompasses other materials such as relatively pure and impurity-doped germanium, gallium arsenide, zinc oxide, glass, and the like. The semiconductor substrate may be a bulk wafer, or may be a thin layer of a semiconductor material, such as silicon, on an insulating layer (commonly know as silicon-on-insulator or SOI) that, in turn, is supported by a carrier wafer. The first region of the semiconductor substrate can be an already-existing fabricated region on, in, or of a semiconductor substrate or a contemplated region on, in, or of the semiconductor substrate, that is, a region designed but yet to be fabricated.

Formulae and processes for obtaining the optical reflectance of materials are well-known. For example, referring to FIG. 11, the optical reflectance (R) of normally incident light on a single material layer 150 bounded on one side by semi-infinite non-absorbing layer 152 (such as, for example, air) and supported by a substrate 154 can be determined by the following equation:

$$R = \frac{( {n}_{0}^{2} + {n}_{1}^{2} ) ( {n}_{1}^{2} + {n}_{2}^{2} ) - 4 {n}_{0} {n}_{1}^{2} {n}_{2} + ( {n}_{0}^{2} - {n}_{1}^{2} ) ( {n}_{1}^{2} - {n}_{2}^{2} ) cos ( 2 {δ}_{1} )}{( {n}_{0}^{2} + {n}_{1}^{2} ) ( {n}_{1}^{2} + {n}_{2}^{2} ) + 4 {n}_{0} {n}_{1}^{2} {n}_{2} + ( {n}_{0}^{2} - {n}_{1}^{2} ) ( {n}_{1}^{2} - {n}_{2}^{2} ) cos ( 2 {δ}_{1} )} , \\ where$$

$${δ}_{1} = \frac{2 π}{λ} {n}_{1} {d}_{1} ,$$

and where the light 158 is transmitted in the single material layer from a light 160 incident on the single material layer, d₁ is the thickness, indicated by double-headed arrow 156, of the single material layer, λ is the wavelength of the light, n₀ is the refractive index of the semi-infinite non-absorbing layer through which the light travels, such as, for example, air, n₁ is the refractive index of the single material layer, and n₂ is the refractive index of the substrate upon which the single material layer is disposed. Methods for obtaining the optical reflectance of a structure with multiple layers, although more complicated, also are available in the art. In an alternative embodiment, the reflectance of a layer or structure with multiple layers can be measured, such as by using a reflectometer. In another alternative embodiment, the reflectance can be calculated using film thicknesses and optical constants that have been measured, such as by an ellipsometer.

The method 50 continues, in accordance with an exemplary embodiment of the present invention, with the fabrication of a second region of the semiconductor region such that it has substantially the same optical reflectance as the first region. In this regard, the optical reflectance of a contemplated or already-existing second region of the semiconductor substrate can be obtained using one or more methods described above. If it is determined that the optical reflectance of the second region differs from the optical reflectance of the first region by more than a threshold limit, then the constitution of the one or both regions can be modified so that the optical reflectance of the regions are substantially equal. In one embodiment of the invention, the threshold limit is about 10%. In another embodiment of the invention, threshold limit is about 5%. In a preferred embodiment, the threshold limit is about 1%. The optical reflectances of the regions are “substantially equal” or “substantially the same” when they differ by no more than about 10%, preferably by no more than about 5%, and more preferably by no more than 1%. A simple example is illustrated in FIGS. 3-6. Referring to FIG. 3, a semiconductor substrate 100 comprises a contemplated first region 60 having a contemplated first material stack 62 and a contemplated second region 64 having a contemplated second material stack 66. Contemplated first material stack 62 has “n” total layers and contemplated second material stack 66 has “m” total layers, wherein n and m are integers. If it is determined that contemplated second region 66 has an optical reflectance that differs from the optical reflectance of contemplated first region 60 by at least the threshold limit, the constitution of first region 60, the constitution of the second region 64, or the constitution of both regions is modified so that the optical reflectance of the two regions are substantially the same.

In one exemplary embodiment, the thickness of at least one material layer within one or both of the materials stacks is modified to modify the constitution(s) thereof. For example, while in FIG. 3 layer “n” of first material stack 62 is illustrated with a first thickness indicated by double-headed arrow 68, the thickness of layer “n” can be decreased or, as illustrated in FIG. 4, increased to a second thickness, indicated by double-headed arrow 70, so that regions 60 and 64 exhibit substantially the same optical reflectance. The modified first region and the contemplated second region then can be fabricated with both regions have substantially the same optical reflectance (step 54).

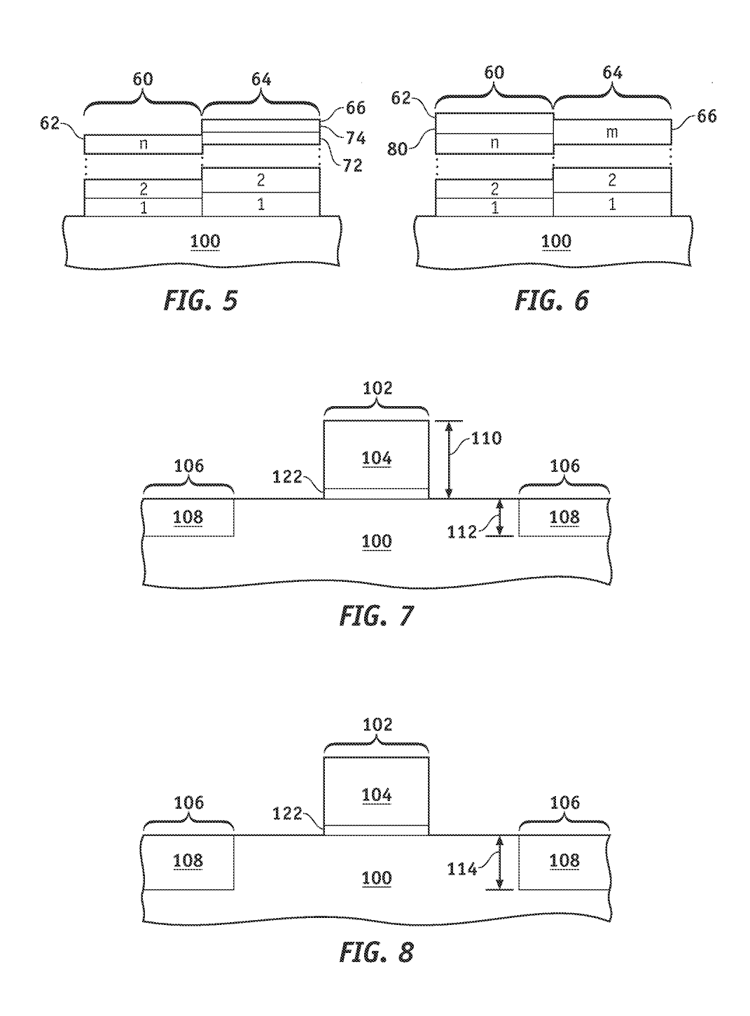

In another exemplary embodiment, the constitution of one or both regions can be modified by modifying the composition of one or more layers of one or both material stacks. For example, a layer, such as layer “m” of FIG. 3, fabricated of a first material can be fabricated from a different, second material. Alternatively, as illustrated in FIG. 5, the composition of a layer, such as layer “m” of FIG. 3, can be modified from a single layer to two layers, such as layers 72 and 74, or more layers having different compositions. The composition and the thickness of the layers 72 and 74 can be configured so that the optical reflectances of the two regions 60 and 64 are substantially the same. The two regions 60 and 64 then can be fabricated with both regions having substantially the same optical reflectance (step 54).

In a further exemplary embodiment, the optical reflectances of the two regions are made substantially similar by the addition of a material layer over one or both regions. For example, as illustrated in FIG. 6, a material layer 80 may be formed overlying the layer n before the first material stack 62 is formed by etching. Material layer 80 and the underlying layers of first material stack 62 then can be etched to form modified first material stack 62 that has an optical reflectance that is substantially the same as second material stack 66. The two regions 60 and 64 then can be fabricated with both regions have substantially the same optical reflectance (step 54). After subsequent annealing as described below, the material layer 80 can be removed from first material stack 62 or can remain thereon depending on the desired application of first material stack 62 and/or on subsequent fabrication steps. While only one material layer 80 is illustrated in FIG. 6 as being formed on first material stack 62, it will be understood that multiple layers of different materials may be formed on one of the regions or one or more layers of different materials may be formed on both regions.

While FIGS. 3-6 illustrate the modification of one or both regions of a semiconductor substrate where the regions comprise layers of materials, it will be understood that the invention is not so limited and that the one or both regions also can be modified by altering structures of the regions. As used herein, the term “structure” means any arrangement of parts, elements, or constituents on or of the semiconductor substrate, including material layers on and/or within the substrate. In one exemplary embodiment, the thickness of a structure in one or both of the regions is modified to modify the constitution(s) thereof. For example, referring to FIG. 7, a semiconductor substrate 100 has a contemplated first region 102 having a gate electrode 104 formed of polycrystalline material and an underlying thermal silicon oxide gate insulator 122 and a contemplated second region 106 having a shallow trench isolation (STI) structure 108 formed of silicon dioxide in a trench within the substrate. A thickness, indicated by double-headed arrow 112, of the STI structure 108 of the contemplated second region 106 can be decreased or, as shown in FIG. 8, increased to a thickness indicated by double-headed arrow 114 so that the optical reflectances of the two regions are substantially the same. The contemplated first region and the modified contemplated second region then can be fabricated with both regions having substantially the same optical reflectance (step 54). Alternatively, or in addition, a thickness, indicated by double-headed arrow 110, of the contemplated gate electrode 104 can be increased or decreased, followed by fabrication of the regions.

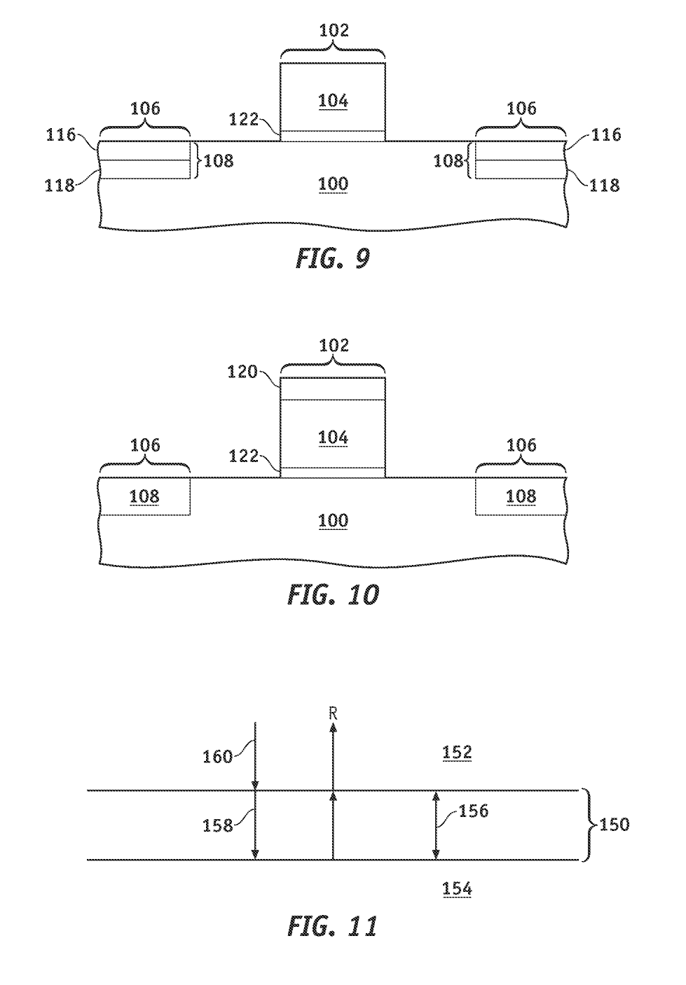

In another exemplary embodiment, the constitution of one or both regions is modified by modifying the composition of one or both of the structures. For example, the STI structure 108 can be fabricated from a material other than silicon dioxide. Alternatively, as illustrated in FIG. 9, the composition of the STI structure 108 can be modified from a single oxide layer to two layers, such as layers 116 and 118, or more layers having different compositions. The compositions of the layers and the thicknesses of the layers can be configured so that the optical reflectances of the two regions 102 and 106 are substantially the same. In addition, or alternatively, the composition of the gate electrode 104 can be modified by fabricating the gate electrode from a material other than polycrystalline silicon. The two regions 102 and 106 then can be fabricated with both regions having substantially the same optical reflectance (step 54).

In yet a further exemplary embodiment, the optical reflectances of the two regions are made substantially similar by the addition of a material layer over one or both structures of the regions. For example, as illustrated in FIG. 10, a material layer 120 may be formed overlying the polycrystalline silicon of gate electrode 104. In this regard, the material layer 120 is formed overlying a layer of polycrystalline silicon before the gate electrode is formed by etching the polycrystalline silicon. Material layer 120 and the polycrystalline silicon both then can be etched to form modified gate electrode 104 such that contemplated first region has an optical reflectance that is substantially the same as contemplated second region 106. The two regions 102 and 106 then can be fabricated with both regions having substantially the same optical reflectance (step 54). After fabrication overlying an actual semiconductor substrate 100, and after subsequent annealing as described below, the material layer 120 may be removed from gate electrode 104 or may remain thereon. While only one material layer 120 is illustrated in FIG. 10, it will be understood that multiple layers of different materials may be formed on a structure or structures of one of the regions or one or more layers of different materials may be formed on a structure or structures of both regions.

After the first and second regions of the semiconductor substrate are fabricated, the semiconductor substrate and, hence, the first and second regions are subjected to optical annealing (step 56). The optical annealing process may include rapid thermal annealing (RTA), rapid thermal cleaning (RTC), rapid thermal chemical vapor deposition (RTCVD), rapid thermal oxidation (RTO), or rapid thermal nitridation (RTN). Because both regions now exhibit substantially the same optical reflectance, during optical annealing, both regions exhibit substantially the same absorption of light. This uniform optical annealing, in turn, results in substantially uniform temperature changes of both regions, which uniformity minimizes deviations from the desired characteristics of devices or structures formed on and within the regions.

Accordingly, methods for fabricating semiconductor structures using a uniform optical annealing process and semiconductor structures fabricated from such methods are provided herein. The methods utilize a comparison of the optical reflectance of a first region of a semiconductor substrate to the optical reflectance of a second region of the semiconductor substrate. The second region then is configured so that it exhibits substantially the same optical reflectance as the first region. While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

1. A method for uniformly optically annealing a semiconductor substrate, the method comprising the steps of:
obtaining an optical reflectance of a first region of the semiconductor substrate;
obtaining an optical reflectance of a contemplated second region of the semiconductor substrate, the contemplated second region having a contemplated material layer;
fabricating a modified second region of the semiconductor substrate such that the optical reflectance of the modified second region is substantially equal to the optical reflectance of the first region, wherein the first region is not the modified second region, and wherein the modified second region has a modified material layer that is a modified version of the contemplated material layer; and
optically annealing the semiconductor substrate.

2. The method of claim 1, wherein the step of fabricating comprises the steps of:
comparing the optical reflectance of the first region to the optical reflectance of the contemplated second region to determine if the optical reflectances differ by at least a threshold limit.

3. The method of claim 2, wherein the step of comparing comprises comparing the optical reflectance of the first region to the optical reflectance of the contemplated second region to determine if the optical reflectances differ by more than 1%.

4. (canceled)

5. The method of claim 1, wherein the step of fabricating comprises the step of fabricating the modified second region wherein the modified material layer has a thickness different from a thickness of the contemplated material layer.

6. The method of claim 1, wherein the step of fabricating comprises the step of fabricating the modified second region wherein the modified material layer has a composition different from a composition of the contemplated material layer.

7. The method of claim 1, wherein the contemplated material layer comprises one layer of a material and wherein the step of fabricating comprises the step of fabricating the modified second region wherein the modified material layer comprises at least two sublayers of different materials.

8. (canceled)

9. The method of claim 1, further comprising modifying the first region.

10. The method of claim 1, wherein the step of optically annealing the semiconductor substrate comprises subjecting the semiconductor substrate to rapid thermal annealing, rapid thermal cleaning, rapid thermal chemical vapor deposition, rapid thermal oxidation, or rapid thermal nitridation.

11. The method of claim 1, wherein the step of fabricating comprises fabricating a second region of the semiconductor substrate such that the optical reflectance of the second region differs from the optical reflectance of the first region by no more than 10%.

12. A method for fabricating semiconductor structures on a semiconductor substrate, the method comprising the steps of:
obtaining an optical reflectance of a contemplated first region of the semiconductor substrate;
comparing the optical reflectance of the contemplated first region to an optical reflectance of a contemplated second region of the semiconductor substrate;
modifying a constitution of the contemplated first region to a constitution of a modified first region if the optical reflectance of the contemplated first region and the optical reflectance of the contemplated second region differ by at least a threshold limit; and
fabricating the modified first region of the semiconductor substrate; and
optically annealing the semiconductor substrate.

13. The method of claim 12, wherein the step of modifying comprises the step of increasing a thickness of a structure of the contemplated first region.

14. The method of claim 12, wherein the step of modifying comprises the step of changing a composition of a structure of the contemplated first region from a first material to a second material different from the first material.

15. The method of claim 12, wherein the step of modifying comprises the step of changing a structure of the contemplated first region from comprising one material layer to comprising more than one material layer.

16. The method of claim 12, wherein the step of modifying comprises the step of adding a material layer to a structure of the contemplated first region.

17. The method of claim 12, further comprising the step of fabricating the contemplated second region of the semiconductor substrate.

18. The method of claim 12, further comprising the steps of:
modifying a constitution of the contemplated second region to a constitution of a modified second region if the optical reflectance of the contemplated first region and the optical reflectance of the contemplated second region are not substantially similar; and
fabricating the modified second region of the semiconductor substrate.

19. The method of claim 12, wherein the step of optically annealing the semiconductor substrate comprises subjecting the semiconductor substrate to rapid thermal annealing, rapid thermal cleaning, rapid thermal chemical vapor deposition, rapid thermal oxidation, or rapid thermal nitridation.

20. The method of claim 12, wherein the step of modifying comprises modifying a constitution of the contemplated first region to a constitution of a modified first region if the optical reflectance of the contemplated first region and the optical reflectance of the contemplated second region differ by more than 1%.
